(19) United States
(12) Patent Application Publication
(10) Pub. No.: US 2025/0107253 A1
(43) Pub. Date: Mar. 27, 2025

(54) Method for manufacturing electronic device

(71) Applicant: InnoLux Corporation, Miao-Li County (TW)

(72) Inventors: Yu-Tsung LIU, Miao-Li County (TW); Yu-Ting TSAI, Miao-Li County (TW); I-An YAO, Miao-Li County (TW)

(21) Appl. No.: 18/816,264

(22) Filed: Aug. 27, 2024

Related U.S. Application Data
(60) Provisional application No. 63/585,708, filed on Sep. 27, 2023.

(30) Foreign Application Priority Data
Jun. 26, 2024 (CN) 202410836607.7

(51) Int. Cl. H01L 27/144; H01L 25/16

(52) U.S. Cl. CPC H10F 39/107; H01L 25/165; H01L 25/167

(57) ABSTRACT

A method for manufacturing an electronic device includes the following steps: providing a carrier and a circuit substrate, wherein the carrier includes a plurality of spacers, the circuit substrate includes a plurality of electronic units, and the electronic units are detected and determined to be normal or defective; providing cover units on the carrier; disposing the circuit substrate on the cover units so that the spacers support the circuit substrate, wherein there is a gap between the circuit substrate and the cover units, and the cover units correspond to the electronic units determined to be normal; vacuuming the gap between the circuit substrate and the cover units; moving the spacers to make the cover units and the circuit substrate contact each other; and pressing the cover units and the circuit substrate to fix the cover units and the circuit substrate to each other.

### CROSS-REFERENCE TO RELATED APPLICATIONS

This application claims the benefits of the Chinese Patent Application Serial Number 202410836607.7, filed on Jun. 26, 2024, the subject matter of which is incorporated herein by reference.

This application claims the benefit of filing date of U.S. Provisional Application Ser. No. 63/585,708, filed Sep. 27, 2023 under 35 USC § 119(e)(1).

### BACKGROUND

### Field

The present disclosure relates to a method for manufacturing an electronic device and, more specifically to a method for manufacturing a package of an electronic device.

### Description of Related Art

Generally, during the manufacturing process of electronic devices, such as during the packaging process, the cover plate and the circuit substrate are assembled, followed by cutting to form a plurality of independent units.

However, in the traditional manufacturing process, there are still situations where the vacuum degree after assembling is not good, or there is material waste due to abnormal packaging of electronic units.

Therefore, it is desirable to provide a method for manufacturing an electronic device to improve the conventional defects.

### SUMMARY

The present disclosure provides a method for manufacturing an electronic device, comprising the following steps: providing a carrier and a circuit substrate, wherein the carrier comprises a plurality of spacers, the circuit substrate comprises a plurality of electronic units, and the plurality of electronic units are detected and determined to be normal or defective; providing a plurality of cover units on the carrier; disposing the circuit substrate on the plurality of cover units so that the plurality of spacers support the circuit substrate, wherein there is a gap between the circuit substrate and the plurality of cover units, and the plurality of cover units correspond to the plurality of electronic units determined to be normal; vacuuming the gap between the circuit substrate and the plurality of cover units; moving the plurality of spacers to make the plurality of cover units and the circuit substrate contact each other; and pressing the plurality of cover units and the circuit substrate to fix the plurality of cover units and the circuit substrate to each other.

The present disclosure further provides a method for manufacturing an electronic device, comprising the following steps: providing a carrier and a circuit substrate, wherein the carrier comprises a plurality of first marks, the circuit substrate comprises a plurality of second marks and a plurality of electronic units, the plurality of second marks and the plurality of electronic units are separated from each other in a top view direction of the carrier, and the plurality of electronic units are detected and determined to be normal or defective; providing a plurality of cover units on the carrier; disposing the circuit substrate on the plurality of cover units so that the plurality of first marks of the carrier and the plurality of second marks of the circuit substrate are overlapped in the top view direction of the carrier, wherein the plurality of cover units correspond to the plurality of electronic units determined to be normal; vacuuming the circuit substrate and the plurality of cover units; and pressing the plurality of cover units and the circuit substrate to fix the plurality of cover units and the circuit substrate to each other.

Other novel features of the disclosure will become more apparent from the following detailed description when taken in conjunction with the accompanying drawings.

### BRIEF DESCRIPTION OF DRAWINGS

FIG. 1 is a flow block diagram of a method for manufacturing an electronic device according to one embodiment of the present disclosure.

FIG. 2A is a top view of a carrier according to one embodiment of the present disclosure.

FIG. 2B is a bottom view of a circuit substrate according to one embodiment of the present disclosure.

FIG. 2C is a top view of a carrier and a circuit substrate after assembling according to one embodiment of the present disclosure.

FIG. 3A and FIG. 3B are cross-sectional views showing a method for manufacturing an electronic device according to one embodiment of the present disclosure.

FIG. 4A and FIG. 4B are cross-sectional views showing part of an electronic device according to one embodiment of the present disclosure.

FIG. 5A and FIG. 5B are cross-sectional views showing part of an electronic device according to one embodiment of the present disclosure.

FIG. 6A is a top view of a carrier according to one embodiment of the present disclosure.

FIG. 6B is a bottom view of a circuit substrate according to one embodiment of the present disclosure.

FIG. 6C is a top view of a carrier and a circuit substrate after assembling according to one embodiment of the present disclosure.

FIG. 7A is a top view of a carrier according to one embodiment of the present disclosure.

FIG. 7B is a bottom view of a circuit substrate according to one embodiment of the present disclosure.

FIG. 7C is a top view of a carrier and a circuit substrate after assembling according to one embodiment of the present disclosure.

FIG. 8A and FIG. 8B are cross-sectional views showing a method for manufacturing an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the distance, the length, the width and the thickness may be measured using an optical microscope or using cross-sectional images in an electron microscope, but the present disclosure is not limited thereto. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

The electronic device of the present disclosure may include a display device, a sensing device, an antenna device, a touch device, a tiled device or other suitable electronic devices; but the present disclosure is not limited thereto. The display device of the present disclosure may be a non-self-luminous display device or a self-luminous display device, such as a liquid crystal display, a cholesteric liquid crystal display, an electro-phoretic display, an organic light emitting diode display or a light emitting diode display; but the present disclosure is not limited thereto. The display device may comprise a light emitting diode, a light conversion layer, other suitable materials or a combination thereof; but the present disclosure is not limited thereto. The light emitting diode may comprise, for example, an organic light emitting diode (OLED), a mini light emitting diode (mini LED), a micro light emitting diode (micro LED) or a quantum dot light emitting diode (quantum dot LED which may include QLED or QDLED); but the present disclosure is not limited thereto. The light conversion layer may comprise wavelength conversion materials and/or filter materials. The light conversion layer may comprise, for example, fluorescence, phosphors, quantum dots (QDs), other suitable materials or a combination thereof; but the present disclosure is not limited thereto. The sensing device may include, for example, a biosensor, a touch sensor, a fingerprint sensor, a temperature sensor, other suitable sensors or a combination of the above types of sensors. The antenna device may, for example, be a liquid crystal antenna or other types of antenna; but the present disclosure is not limited thereto. The tiled device may, for example, be a tiled display device or a tiled antenna device; but the present disclosure is not limited thereto. The electronic device may comprise an electronic unit, which may comprise a passive component, an active component or a combination thereof, such as a capacitor, a resistor, an inductor, a varactor diode, a variable capacitor, a filter, a diode, a transistor, a sensor, a microelectromechanical system (MEMS), or a chip; but the present disclosure is not limited thereto. It should be noted that the electronic device of the present disclosure may be any combination of the above devices; but the present disclosure is not limited thereto.

Without departing from the spirit of the present disclosure, features in several different embodiments can be replaced, reorganized, and mixed to complete other embodiments.

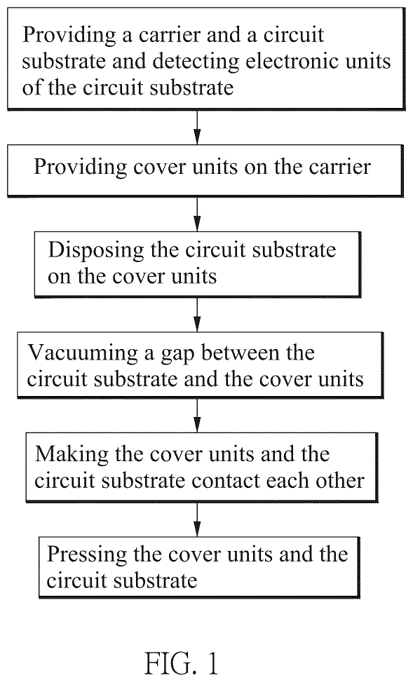

FIG. 1 is a flow block diagram of a method for manufacturing an electronic device according to one embodiment of the present disclosure.

In one embodiment of the present disclosure, as shown in FIG. 1, a method for manufacturing an electronic device may comprise: providing a carrier and a circuit substrate and detecting electronic units of the circuit substrate; providing cover units on the carrier; disposing the circuit substrate on the cover units; vacuuming a gap between the circuit substrate and the cover units; making the cover units and the circuit substrate contact each other; and pressing the cover units and the circuit substrate to fix the cover units and the circuit substrate. Thus, the purpose of packaging and assembling the cover unit and the circuit substrate can be achieved. The features of each step will be disclosed in detail below.

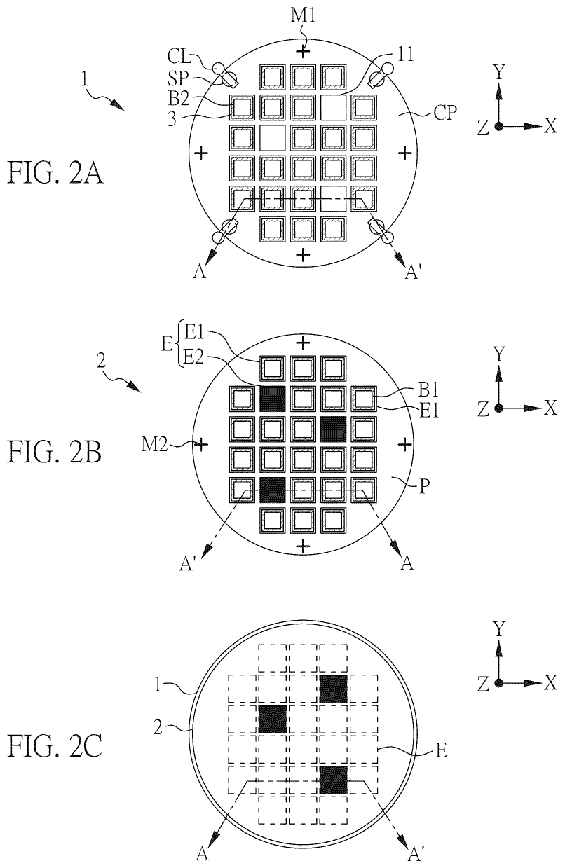

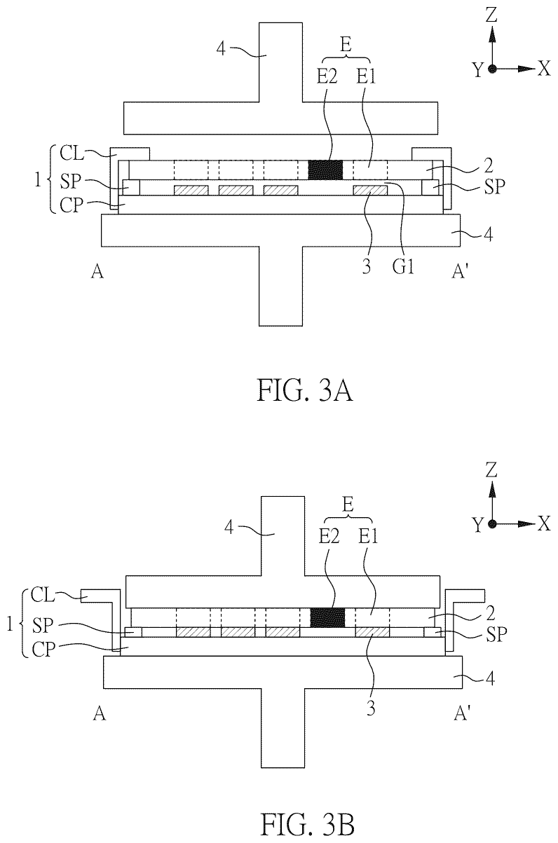

FIG. 2A is a top view of a carrier according to one embodiment of the present disclosure. FIG. 2B is a bottom view of a circuit substrate according to one embodiment of the present disclosure. FIG. 2C is a top view of a carrier and a circuit substrate after assembling according to one embodiment of the present disclosure. FIG. 3A and FIG. 3B are cross-sectional views showing a method for manufacturing an electronic device according to one embodiment of the present disclosure, wherein FIG. 3A and FIG. 3B show the cross-sectional views of the carrier and the circuit substrate along the line A-A′ in FIG. 2A to FIG. 2C.

In one embodiment of the present disclosure, the method for manufacturing an electronic device comprises the following steps. A carrier 1 and a circuit substrate 2 are provided, wherein, as shown in FIG. 2A and FIG. 2B, the carrier 1 may comprise a plurality of spacers SP; the circuit substrate 2 may comprise a plurality of electronic units E and the electronic units E are detected and determined to be normal or defective. Herein, the defective electronic unit E2 is represented by a black filling pattern in FIG. 2B. Next, a plurality of cover units 3 are provided on the carrier 1. In the present disclosure, the “normal electronic unit E1” refers to, for example, the appearance and the electrical properties of the electronic unit E are normal and the electronic unit E can be operated. The “defective electronic unit E2” refers to the appearance, the electrical properties or a combination thereof of the electronic unit E is abnormal, resulting in abnormal operation of the electronic unit E. Thus, the step of detecting the electronic unit E may comprise: performing electrical testing, electrostatic discharge testing, visual inspection, other appropriate testing or a combination thereof on the electronic unit E; but the present disclosure is not limited thereto.

Then, as shown in FIG. 3A, the circuit substrate 2 is disposed on the cover units 3 so that the spacers SP can support the circuit substrate 2, wherein there is a gap G1 between the circuit substrate 2 and the cover units 3, and the cover units 3 correspond to the normal electronic units E1 (i.e. the electronic units E1 determined to be normal). In one embodiment of the present disclosure, the cover units 3 may not be disposed on the carrier 1 at the position corresponding to the defective electronic unit E2 (i.e. the electronic unit E2 determined to be defective). In this way, the waste of cover units 3 can be reduced and the manufacturing cost can be reduced. Then, the gap G1 between the circuit substrate 2 and the cover unit 3 is vacuumed. More specifically, for example, the circuit substrate 2 and the carrier 1 with the cover units 3 disposed thereon may be placed in a reaction chamber (not shown in the figure) first and then the reaction chamber is vacuumed; but the present disclosure is not limited thereto. In the present disclosure, since the spacers SP can provide support, so the gap G1 can be created between the circuit substrate 2 and the cover units 3, which will facilitate the vacuuming step and improving the vacuum effect between the circuit substrate 2 and the cover units 3. In the present disclosure, the “vacuum” means that the pressure in the reaction chamber is, for example, less than or equal to 1 torr. For example, the pressure in the reaction chamber may be 10⁻³ torr to 1 torr or 10⁻⁷ torr to 1 torr; but the present disclosure is not limited thereto. In one embodiment of the present disclosure, a step of pre-heating the cover units 3 and/or the circuit substrate 2 may be performed before the step of making the cover units 3 and the circuit substrate 2 contact each other. The pre-heating step may be, for example, to evaporate the water vapor on the cover units 3 and/or the circuit substrate 2 or to volatilize the organic solvent in the cover units 3 and/or the circuit substrate 2 by heating. In this way, the vacuum inside the final product can be increased.

Next, as shown in FIG. 3B, the spacers SP are moved to make the cover units 3 and the circuit substrate 2 contact each other. Herein, the circuit substrate 2 may be in contact with the spacers SP and the cover units 3 respectively; but the present disclosure is not limited thereto. Then, the cover units 3 and the circuit substrate 2 are pressed to fix the cover units 3 and the circuit substrate 2 to each other, thereby forming the structure shown in FIG. 2C.

In the present disclosure, the electronic units E may comprise a drive circuit, a transistor, a thermal sensing component, a sensing component, a microelectromechanical system or a combination thereof; but the present disclosure is not limited thereto. In the present disclosure, the material of the cover units 3 may comprise silicon, germanium (Ge), zinc sulfide (ZnS), zinc selenide (ZnSe), gallium arsenide (GaAs), chalcogenide or a combination thereof; but the present disclosure is not limited thereto. In one embodiment of the present disclosure, for example, light in specific wavelength range (for example, light with wavelengths of 5 μm to 15 μm) can penetrate through the cover units 3; but the present disclosure is not limited thereto. In the present disclosure, the material of the spacer SP may comprise a metal, an alloy, stainless steel or a combination thereof. The metal may be, for example, copper, nickel, brass or a combination thereof; but the present disclosure is not limited thereto. In one embodiment of the present disclosure, as shown in FIG. 2B, from the top view direction Z of the circuit substrate 2, the circuit substrate 2 may be circular; but the present disclosure is not limited thereto.

In one embodiment of the present disclosure, as shown in FIG. 2A and FIG. 3A, the carrier 1 may further comprise a carrier portion CP and a plurality of fixing units CL, wherein the carrier portion CP is used for carrying the cover units 3, and the fixing units CL are used for fixing the carrier portion CP of the carrier 1 and the circuit substrate 2. The carrier 1 and the circuit substrate 2 are fixed by the fixing units CL before the vacuuming step, and the fixing of the fixing units CL is released after the vacuuming step is started, as shown in FIG. 3B. More specifically, in one embodiment of the present disclosure, after the vacuuming step is started, for example, the fixing units CL may be removed first, and then the spacers SP are moved so that the cover unit 3 and the circuit substrate 2 contact to each other to perform the sequential steps. In one embodiment of the present disclosure, as shown in FIG. 2A and FIG. 3A, in the top view direction Z of the carrier 1, the fixing units CL, part of the circuit substrate 2 and the spacers SP may be partially overlapped; but the present disclosure is not limited thereto. In other embodiments of the present disclosure, even not shown in the figure, the fixing units CL and the spacers SP may be adjacently disposed. That is, in the top view direction Z of the carrier 1, the fixing units CL and the spacers SP may not be overlapped. In the present disclosure, the material of the carrier portion CP may comprise, for example, a metal, a stainless steel or other suitable materials. In the present disclosure, as shown in FIG. 2A, in the top view direction Z of the carrier 1, the carrier portion CP may be circular; but the present disclosure is not limited thereto. In the present disclosure, the fixing units CL may comprise an elastic material. For example, the material of the fixing units CL may comprise a metal, an alloy thereof, a stainless steel or a combination thereof, wherein the metal may comprise, for example, copper, nickel, brass or a combination thereof; but the present disclosure is not limited thereto. In one embodiment of the present disclosure, the fixing units CL may be, for example, clamps; but the present disclosure is not limited thereto.

In one embodiment of the present disclosure, as shown in FIG. 2A, the carrier portions CP of the carrier 1 may further comprise a plurality of limiting portions 11 corresponding to the cover units 3. More specifically, the limiting portions 11 may be used to accommodate the cover units 3, and the cover units 3 and the limiting portions 11 are overlapped in the top view direction Z of the carrier 1. Thus, in FIG. 2A, the cover units 3 may be disposed on the limiting portions 11 corresponding to the normal electronic units E1, but the cover units 3 may not be disposed on the limiting portions 11 corresponding to the defective electronic units E2, thereby exposing the limiting portions 11.

In one embodiment of the present disclosure, as shown in FIG. 2A and FIG. 2B, the carrier portion CP of the carrier 1 may comprise a plurality of first marks M1, the circuit substrate 2 may comprise a connection portion P and a plurality of second marks M2, and the second marks M2 may be disposed on the connection portion P. Herein, before the step of pressing the cover units 3 and the circuit substrate 2, the method may further comprise: making the first marks M1 of the carrier 1 and the second marks M2 of the circuit substrate 2 overlap in the top view direction Z of the carrier 1. Then, the assembling step of pressing the cover units 3 and the circuit substrate 2 is performed. In the present disclosure, the first marks M1 and the second marks M2 may be used as positioning marks, which are used to align and assemble the cover units 3 and the circuit substrate 2 to make the cover units 3 correspond to the normal electronic units E1, as shown in FIG. 3A. In the present disclosure, as shown in FIG. 2A and FIG. 2B, in the top view direction Z of the carrier 1 or the circuit substrate 2, the first marks M1 and the spacers SP or the fixing units CL are not overlapped, and the second marks M2 and the electronic units E are not overlapped. Thus, the assembling accuracy of the cover units 3 and the circuit substrate 2 can be improved. In one embodiment of the present disclosure, the first marks M1 and the second marks M2 may respectively be a protrusion structure, a recess structure or a combination thereof. The protrusion structure refers to that, for example, the first mark M1 protrudes towards the circuit substrate 2, and/or the second mark M2 protrudes towards the cover unit 3 when assembling the cover units 3 and the circuit substrate 2. The recess structure refers to that, for example, the first mark M1 is recessed away from the circuit substrate 2, and/or the second mark M2 is recessed away from the cover unit 3 when assembling the cover unit 3 and the circuit substrate 2. In one embodiment of the present disclosure, the shapes of the first marks M1 and the second marks M2 are not particularly limited. For example, as shown in FIG. 2A and FIG. 2B, in the top view direction Z of the carrier 1 or the circuit substrate 2, the first marks M1 and the second marks M2 may respectively be in the shape of “+”; but the present disclosure is not limited thereto. In other embodiments of the present disclosure, the first marks M1 and the second marks M2 may have, for example, a circular shape, a rectangular shape, an uppercase L shape or other suitable shapes. In the present disclosure, the connection portion P of the circuit substrate 2 refers to, for example, the region of the circuit substrate 2 without the circuit, and the connection portion P may surround the plurality of electronic units E; but the present disclosure is not limited thereto.

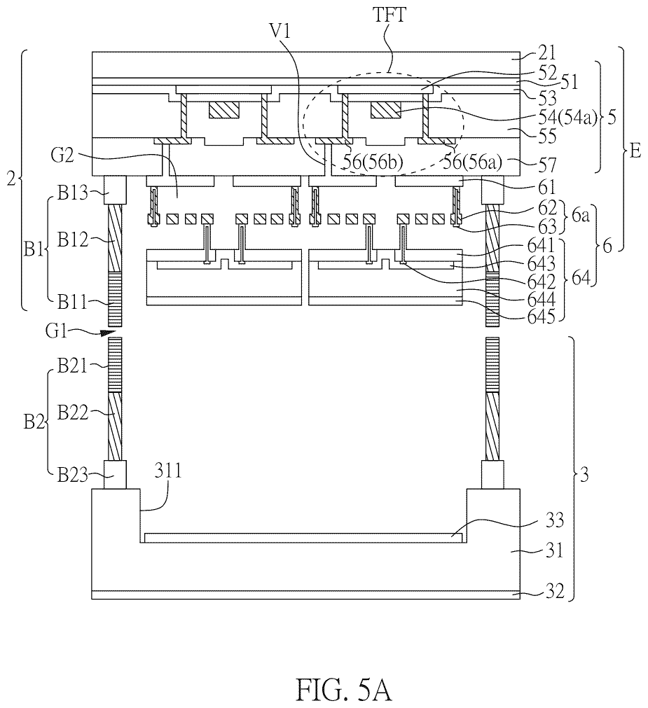

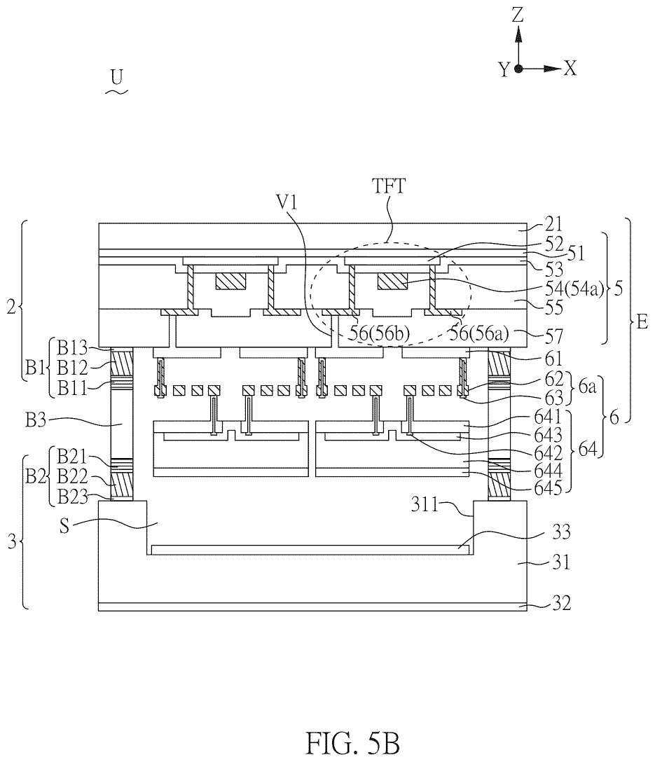

In one embodiment of the present disclosure, before the step of providing the cover units 3 on the carrier 1, the method may further comprise: forming a first adhesive material B1 on the electronic units E and forming a second adhesive material B2 on a substrate 31 (for example, as shown in FIG. 5A) of the cover unit 3. More specifically, as shown in FIG. 2B, for example, the electronic units E may be formed first, and the electronic units E may be detected and determined to be normal or defective, and then the first adhesive material B1 may be formed on the electronic units E. Herein, in the top view direction Z of the circuit substrate 2, the first adhesive material B1 and the electronic units E may be overlapped. As shown in FIG. 2A, for example, the second adhesive material B2 may be formed on the substrate 31 (for example, as shown in FIG. 5A) of the cover unit 3 first, and the cover units 3 are provided on the carrier 1. In one embodiment of the present disclosure, after the step of pressing the cover units 3 and the circuit substrate 2, the first adhesive material B1 and the second adhesive material B2 are bonded to form a third adhesive material B3 (as shown in FIG. 5B), so that the cover units 3 and the circuit substrate 2 are fixed to each other. In one embodiment of the present disclosure, when the first marks M1 of the carrier 1 and the second marks M2 of the circuit substrate 2 are overlapped in the top view direction Z of the carrier 1, the first adhesive material B1 and the second adhesive material B2 may be at least partially overlapped in the top view direction Z of the carrier 1. In the present disclosure, the first adhesive material B1 and the second adhesive material B2 may be the same or different. The first adhesive material B1 and the second adhesive material B2 may respectively comprise a metal, an alloy thereof, a frit paste or a combination thereof. The metal may comprise, for example, gold, silver, copper, aluminum, chromium, platinum, titanium, nickel, tin, tungsten, palladium, molybdenum, zinc or a combination thereof; but the present disclosure is not limited thereto.

In one embodiment of the present disclosure, as shown in FIG. 3B, the step of pressing the cover units 3 and the circuit substrate 2 may further comprise: heating the first adhesive material B1 and the second adhesive material B2 to bond the first adhesive material B1 and the second adhesive material B2 to form the third adhesive material B3 (as shown in FIG. 5B). In the present disclosure, the temperature for heating the first adhesive material B1 and the second adhesive material B2 may be, for example, 90° C. to 450° C., 150° C. to 450° C. or 200° C. to 400° C., and this temperature may be greater than the temperature for the-heating; but the present disclosure is not limited thereto. In one embodiment of the present disclosure, the step of pressing the cover unit 3 and the circuit substrate 2 may further comprise: applying a pressure to the first adhesive material B1 and the second adhesive material B2 to bond the first adhesive material B1 and the second adhesive material B2 to form the third adhesive material B3 (as shown in FIG. 5B). In the present disclosure, the pressure applying to the first adhesive material B1 and the second adhesive material B2 refers to, for example, applying a stress greater than 0.1 MPa during the pressing step; but the present disclosure is not limited thereto. In one embodiment of the present disclosure, as shown in FIG. 3A and FIG. 3B, for example, a movable press machine 4 may be used to apply a pressure to the first adhesive material B1 and the second adhesive material B2; but the present disclosure is not limited thereto.

In one embodiment of the present disclosure, before the step of providing the cover units 3 on the carrier 1, the method may further comprise: providing a mother substrate (not shown in the figure), wherein the mother substrate (not shown in the figure) may be provided with a plurality of adjacent cover units 3; forming a second adhesive material B2 on the cover units 3; and cutting the mother substrate (not shown in the figure) to form cover units 3 (for example, any cover unit 3 shown in FIG. 2A) separated from each other. In one embodiment of the present disclosure, after pressing the cover units 3 and the circuit substrate 2, the method for manufacturing the electronic device may further comprise: cutting the circuit substrate 2 to form a plurality of units U (as shown in FIG. 5B). In the present disclosure, the step of cutting the mother substrate may be performed through wheel cutting, laser cutting or a combination thereof; but the present disclosure is not limited thereto.

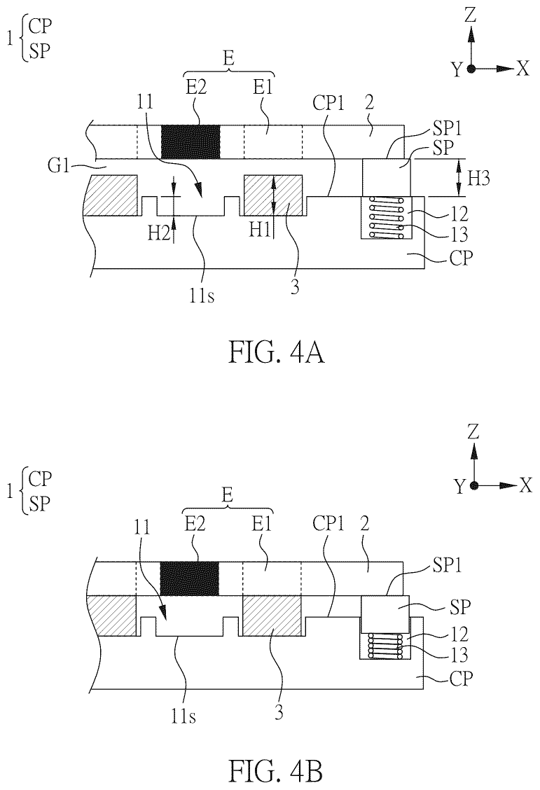

FIG. 4A and FIG. 4B are cross-sectional views showing part of an electronic device according to one embodiment of the present disclosure. Herein, FIG. 4A is a schematic view before moving the spacer, and FIG. 4B is a schematic view after moving the spacer.

In one embodiment of the present disclosure, as shown in FIG. 4A, when the circuit substrate 2 is disposed on the cover units 3 so that the spacers SP support the circuit substrate 2, there is a gap G1 between the circuit substrate 2 and the cover units 3, and the circuit substrate 2 may be in contact with the spacers SP. At this time, the cover units 3 may correspond to the normal electronic units E1, and the cover unit 3 is not disposed corresponding to the defective electronic unit E2 to expose the limiting portion 11. The “limiting portion” refers to, for example, a portion of the carrier portion CP of the carrier 1 that the surface of the carrier portion CP is recessed toward a direction away from the circuit substrate 2.

In the present disclosure, as shown in FIG. 4A, the cover unit 3 has a height H1 which may range from 0.3 mm to 2 mm (0.3 mm≤height H1≤2 mm), for example, from 0.5 mm to 2 mm or from 0.5 mm to 1 mm; but the present disclosure is not limited thereto. The “height of the cover unit” refers to, for example, the maximum size of the cover unit 3 in the top view direction Z of the carrier 1. In the present disclosure, the limiting portion 11 has a depth H2 which may range from 0.1 mm to 1 mm (0.1 mm≤depth H2≤1 mm), for example, from 0.1 mm to 0.8 mm or from 0.1 mm to 0.5 mm; but the present disclosure is not limited thereto. The “depth of the limiting portion” refers to, for example, the maximum distance from the top surface CP1 of the carrier portion CP to the recess surface 11s in the top view direction Z of the carrier 1. In the present disclosure, the spacer SP has a height H3 which may range from 0.3 mm to 2 mm (0.3 mm≤height H3≤2 mm), for example, from 0.5 mm to 2 mm or from 0.5 mm to 1 mm; but the present disclosure is not limited thereto. The “height of the spacer” refers to, for example, the maximum size from the top surface SP1 of the spacer SP to the top surface CP1 of the carrier portion CP in the top view direction Z of the carrier 1.

In one embodiment of the present disclosure, as shown in FIG. 4B, after the step of moving the spacers SP to make the cover units 3 and the circuit substrate 2 contact each other, the circuit substrate 2 may be in contact with the spacer SP and the cover units 3 respectively. More specifically, as shown in FIG. 4A and FIG. 4B, the carrier portion CP of the carrier 1 may further comprise a plurality of accommodation spaces 12 respectively corresponding to the spacers SP. When moving the spacers SP, at least part of the spacer SP may be moved to the accommodation space 12 so that the spacers SP and the cover units 3 are coplanar, and the circuit substrate 2 may be in contact with the spacers SP and the cover units 3 respectively. In one embodiment of the present disclosure, as shown in FIG. 4A and FIG. 4B, the purpose of moving part of the spacer SP to the accommodation space 12 may be achieved by arranging an elastic component such as a spring 13 in the accommodation space 12 and applying stress to the spacer SP; but the present disclosure is not limited thereto.

FIG. 5A and FIG. 5B are cross-sectional views showing part of an electronic device according to one embodiment of the present disclosure. FIG. 5A is a partial enlarged view of FIG. 3A, and FIG. 5B is a partial enlarged view of FIG. 3B.

In one embodiment of the present disclosure, as shown in FIG. 5A, the circuit substrate 2 comprises: an electronic unit E; and a first adhesive material B1 disposed on the electronic unit E. In one embodiment of the present disclosure, as shown in FIG. 3A and FIG. 5A, the circuit substrate 2 is disposed on the cover unit 3, and there is a gap G1 between the circuit substrate 2 and the cover unit 3 when the spacers SP support the circuit substrate 2. More specifically, as shown in FIG. 5A, the gap G1 refers to, for example, the gap between the first adhesive material B1 of the circuit substrate 2 and the second adhesive material B2 of the cover unit 3. In one embodiment of the present disclosure, as shown in FIG. 3B and FIG. 5B, when performing the step of pressing the cover units 3 and the circuit substrate 2, i.e. when applying heat, pressure or a combination thereof to the first adhesive material B1 and the second adhesive material B2, the first adhesive material B1 and the second adhesive material B2 are bonded to form the third adhesive material B3 to achieve the purpose of fixing the cover units 3 and the circuit substrate 2. In the present disclosure, the third adhesive material B3 may be a compound generated by part of the first adhesive material B1 and part of the second adhesive material B2 after a chemical reaction. Thus, the third adhesive material B3 may be different from the first adhesive material B1 and the second adhesive material B2; but the present disclosure is not limited thereto. In the present disclosure, a sealed space S between the cover unit 3 and the circuit substrate 2 may be formed by the first adhesive material B1, the second adhesive material B2 and the third adhesive material B3. The sealed space S may be vacuum or close to vacuum, which can reduce the interference of other external environments (such as water, vapor, air, etc.) on the electronic unit E.

In one embodiment of the present disclosure, as shown in FIG. 5A, the first adhesive material B1 may comprise a first sub-metal layer B11, a second sub-metal layer B12 and a third sub-metal layer B13, wherein the second sub-metal layer B12 is disposed between the first sub-metal layer B11 and the third sub-metal layer B13; the second adhesive material B2 may comprise a fourth sub-metal layer B21, a fifth sub-metal layer B22 and a sixth sub-metal layer B23, wherein the fifth sub-metal layer B22 is disposed between the fourth sub-metal layer B21 and the sixth sub-metal layer B23. When heat, pressure or a combination thereof is applied to the first adhesive material B1 and the second adhesive material B2, a third adhesive material B3 may be generated by part of the first sub-metal layer B11 of the first adhesive material Bland part of the fourth sub-metal layer B21 of the second adhesive material B2 through chemical reaction, wherein the third adhesive material B3 is disposed between the first sub-metal layer B11 and the fourth sub-metal layer B21.

In the present disclosure, the material of the first sub-metal layer B11 and the material of the fourth sub-metal layer B21 may be the same or different. The material of the first sub-metal layer B11 and the material of the fourth sub-metal layer B21 may respectively comprise, for example, copper, tin, gold, nickel or a combination thereof; but the present disclosure is not limited thereto. The material of the second sub-metal layer B12 and the material of the fifth sub-metal layer B22 may be the same or different. The material of the second sub-metal layer B12 and the material of the fifth sub-metal layer B22 may respectively comprise, for example, copper, tin, gold, nickel or a combination thereof. The material of the third sub-metal layer B13 and the material of the sixth sub-metal layer B23 may be the same or different. The material of the third sub-metal layer B13 and the material of the sixth sub-metal layer B23 may respectively comprise, for example, molybdenum, copper, titanium or a combination thereof; but the present disclosure is not limited thereto. In the present disclosure, the material of the first sub-metal layer B11 is different from the material of the second sub-metal layer B12, and the material of the fourth sub-metal layer B21 is different from the material of the fifth sub-metal layer B22. In one embodiment of the present disclosure, the third adhesive material B3 may be, for example, a copper-tin compound such as Cu₃Sn; but the present disclosure is not limited thereto.

In one embodiment of the present disclosure, after the step of pressing the cover units 3 and the circuit substrate 2, the method for manufacturing the electronic device may further comprising a step of: cutting the circuit substrate 2 to form a plurality of units U as shown in FIG. 5B. In the present disclosure, the electronic device may comprise a single unit U or a plurality of units U. In the present disclosure, the unit U may be used to receive or release signals, for example, receive signals with specific wavelengths or release signals with specific wavelengths; but the present disclosure is not limited thereto.

In one embodiment of the present disclosure, as shown in FIG. 5A and FIG. 5B, the electronic unit E may comprise, for example: a substrate 21; a driving circuit 5 disposed on the substrate 21; and a sensing element 6 disposed on the driving circuit 5 and electrically connected to the driving circuit 5. The driving circuit 5 may comprise, for example: a buffer layer 51 disposed on the substrate 21; an active layer 52 disposed on the buffer layer 51; a first insulating layer 53 disposed on the active layer 52; a first metal layer 54 disposed on the first insulating layer 53 and comprising a gate electrode 54a; a second insulating layer 55 disposed on the first metal layer 54; a second metal layer 56 disposed on the second insulating layer 55 and comprising a source electrode 56a and a drain electrode 56b; and a third insulating layer 57 disposed on the second metal layer 56, wherein the active layer 52, the first insulating layer 53, the gate electrode 54a, the second insulating layer 55, the source electrode 56a and the drain electrode 56b form a transistor TFT. The sensing element 6 may comprise, for example: a reflective layer 61 disposed on the third insulating layer 57, wherein the reflective layer 61 may be electrically connected to the drain electrode 56b through a via V1 of the third insulating layer 57; a support layer 62 disposed on the reflective layer 61; a third metal layer 63 disposed on the support layer 62, wherein the support layer 62 and the third metal layer 63 may form a support element 6a to support a sensing unit 64 above; and a sensing unit 64 disposed on the support element 6a. The sensing unit 64 may comprise: an absorbent layer 641 disposed on the support layer 62; a fourth metal layer 642 disposed on the absorbent layer 641; a first passivation layer 643 disposed on the absorbent layer 641 and the fourth metal layer 642; a sensing layer 644 disposed on the first passivation layer 643; and a second passivation layer 645 disposed on the sensing layer 644. In the present disclosure, the absorbent layer 641 may absorb light in specific wavelength range to generate heat, and the generated heat is transmitted to the sensing layer 644 through the fourth metal layer 642 and the first passivation layer 643. The resistance of the sensing layer 644 is changed as the heat changes to form an electrical signal, thereby allowing the sensing element 6 to sense light in specific wavelength range. In the present disclosure, the specific wavelength range may be, for example, between 8 μm and 14 μm; but the present disclosure is not limited thereto. In the present disclosure, the support layer 6a enables a gap G2 formed between the sensing unit 64 and the reflective layer 61. The gap G2 may be formed by respectively disposing a sacrificial layer (not shown in the figure) on the reflective layer 61 and the support element 6a, followed by removing the sacrificial layer (not shown in the figure). The gap G2 may be used to prevent heat conduction which may affect sensing signals.

In the present disclosure, the substrate 21 may be a rigid substrate or a flexible substrate. The material of the substrate 21 may comprise quartz, glass, wafer, sapphire, resin, epoxy resin, polycarbonate (PC), polyimide (PI), polypropylene (PP), polyethylene terephthalate (PET), polymethylmethacrylate (PMMA), other plastic material or a combination thereof, but the present disclosure is not limited thereto. In the present disclosure, the materials of the buffer layer 51, the first insulating layer 53, the second insulating layer 55 and the third insulating layer 57 may be the same or different. The materials of the buffer layer 51, the first insulating layer 53, the second insulating layer 55 and the third insulating layer 57 may respectively comprise silicon nitride, silicon oxide, silicon oxynitride, silicon carbonitride or a combination thereof; but the present disclosure is not limited thereto. In the present disclosure, the material of the active layer 52 may comprise amorphous silicon, polycrystalline silicon (such as low-temperature polycrystalline silicon (LTPS)) or an oxide semiconductor (such as indium gallium zinc oxide (IGZO)); but the present disclosure is not limited thereto. In the present disclosure, the materials of the first metal layer 54, the second metal layer 56 and the reflective layer 61 may be the same or different, wherein the materials of the first metal layer 54, the second metal layer 56 and the reflective layer 61 may respectively comprise gold, silver, copper, palladium, platinum (Pt), ruthenium (Ru), aluminum, cobalt, nickel, titanium, molybdenum (Mo), manganese, zinc, an alloy thereof or a combination thereof; but the present disclosure is not limited thereto.

In the present disclosure, the material of the support layer 62 may comprise titanium nitride (TiN), titanium aluminide (TiAl), titanium aluminium nitride (TiAlN), titanium aluminum oxide (TiAlO), titanium silicon aluminum (TiSiAl), titanium tungsten (TiW), titanium tungsten nitride (TiWN), aluminum nitride (AlNx) or a combination thereof; but the present disclosure is not limited thereto. In the present disclosure, the materials of the third metal layer 63 and the fourth metal layer 642 may be the same or different, wherein the materials of the third metal layer 63 and the fourth metal layer 642 may respectively comprise molybdenum, molybdenum nitride (MoN), molybdenum tungsten (MoW), tungsten or a combination thereof; but the present disclosure is not limited thereto. In the present disclosure, the material of the absorbent layer 641 may comprise titanium, titanium nitride (TiN), platinum, gold, nickel, niobium (Nb), an alloy thereof or a combination thereof; but the present disclosure is not limited thereto. In the present disclosure, the materials of the first passivation layer 643 and the second passivation layer 645 may be the same or different, wherein the materials of the first passivation layer 643 and the second passivation layer 645 may respectively comprise silicon oxide, silicon oxynitride, silicon nitride, aluminum oxide, resin, polymer, photoresist material or a combination thereof; but the present disclosure is not limited thereto. In the present disclosure, the material of the sensing layer 644 may comprise amorphous silicon, vanadium oxide (VOx), yttrium barium copper oxide (YBaCuO), silicon germanium oxide (GeSiO), silicon-germanium (SiGe), bismuth lanthanum strontium manganese oxide (BiLaSrMnO) or a combination thereof; but the present disclosure is not limited thereto. In one embodiment of the present disclosure, the sensing layer 644 may comprise a thermistor; but the present disclosure is not limited thereto.

In one embodiment of the present disclosure, as shown in FIG. 5A and FIG. 5B, the cover unit 3 may comprise: a substrate 31; a first optical film 32 disposed on a side of the substrate 31 away from the circuit substrate 2; a second optical film 33 disposed on a side of the substrate 31 close to the circuit substrate 2; and a second adhesive material B2 disposed on the substrate 31. The first optical film 32 and the second optical film 33 may be used to reduce the reflection of incident light and/or block light in unwanted wavelength ranges to increase the transmittance of light in a specified wavelength range, thereby improving the sensing effect of sensing element 5. In one embodiment of the present disclosure, at least one of the first optical film 32 and the second optical film 33 may be selected to be disposed. For example, the cover unit 3 may comprise the first optical film 32 but may not comprise the second optical film 33; or the cover unit 3 may comprise the second optical film 33 but may not comprise the first optical film 32; or the cover unit 3 may comprise both the first optical film 32 and the second optical film 33. In one embodiment of the present disclosure, the substrate 31 may have a recess 311, wherein the second optical film 33 may be disposed in the recess 311; but the present disclosure is not limited thereto. In the present disclosure, the material of the substrate 31 may comprise silicon, germanium (Ge), zinc sulfide (ZnS), zinc selenide (ZnSe), gallium arsenide (GaAs), chalcogenide or a combination thereof; but the present disclosure is not limited thereto. In the present disclosure, the materials of the first optical film 32 and the second optical film 33 may be the same or different, wherein the materials of the first optical film 32 and the second optical film 33 may respectively comprise germanium (Ge), zinc sulfide (ZnS), zinc selenide (ZnSe), magnesium fluoride (MgF₂), beryllium fluoride (BeF₂), potassium chloride, arsenic trisulfide (As₂S₃) or a combination thereof; but the present disclosure is not limited thereto.

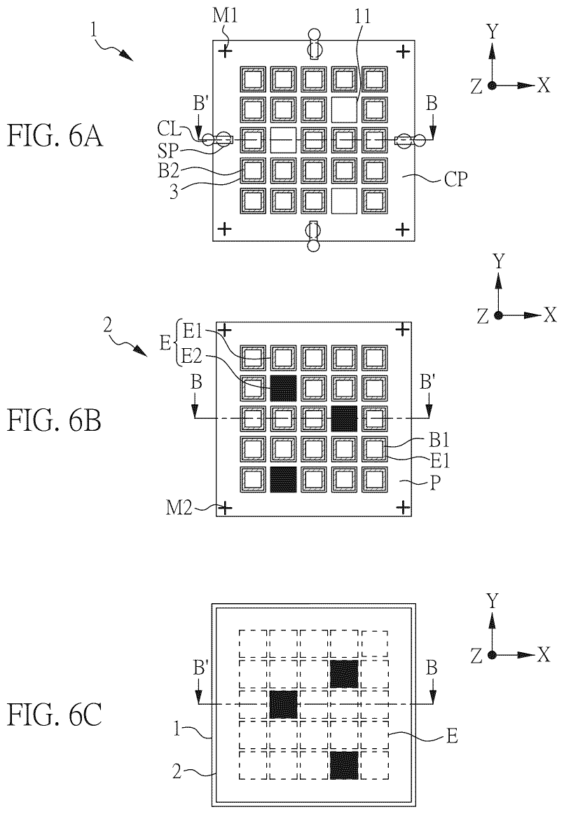

FIG. 6A is a top view of a carrier according to one embodiment of the present disclosure. FIG. 6B is a bottom view of a circuit substrate according to one embodiment of the present disclosure. FIG. 6C is a top view of a carrier and a circuit substrate after assembling according to one embodiment of the present disclosure. The carrier and the circuit substrate shown in FIG. 6A to FIG. 6C are similar to those shown in FIG. 2A to FIG. 2C, except for the following differences.

In one embodiment of the present disclosure, as shown in FIG. 6A to FIG. 6C, when observing from the top view direction Z of the carrier 1 or the circuit substrate 2, the carrier portion CP of the carrier 1 and the circuit substrate 2 may be respectively rectangular; but the present disclosure is not limited thereto. Even not shown in the figure, in other embodiments of the present disclosure, in addition to the circular shapes shown in FIG. 2A to FIG. 2C and the rectangular shapes shown in FIG. 6A to FIG. 6C, the shapes of the carrier portion CP of the carrier 1 and the circuit substrate 2 may be designed according to the needs, and may be, for example, ellipse, prismatic or other suitable shapes. In one embodiment of the present disclosure, the shapes of the carrier portion CP of the carrier 1 and the circuit substrate 2 may be the same or different.

In the present disclosure, since the carrier 1 and the circuit substrate 2 shown in FIG. 6A to FIG. 6C are similar to those shown in FIG. 2A to FIG. 2C, the carrier 1 and the circuit substrate 2 shown in FIG. 3A and FIG. 3B can also be regarded as the cross-sectional views of line B-B′ shown in FIG. 6A to FIG. 6C. The detailed features are as mentioned above and will not be repeated here.

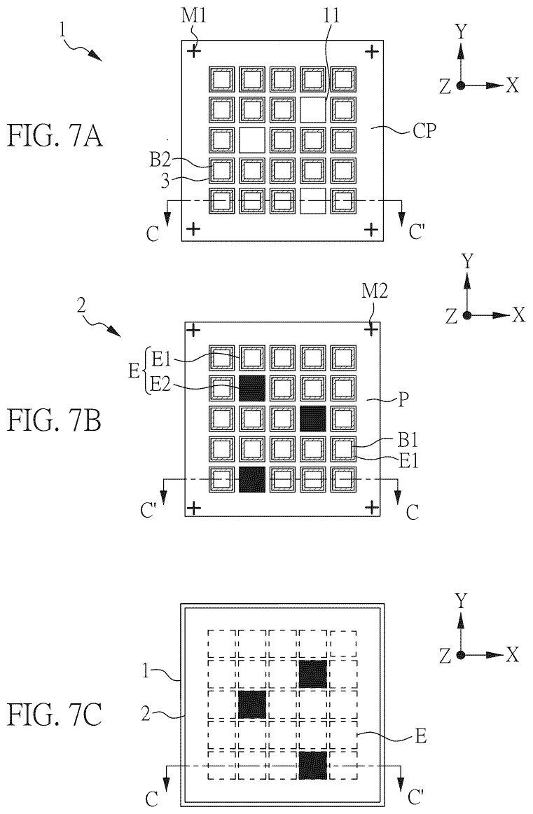

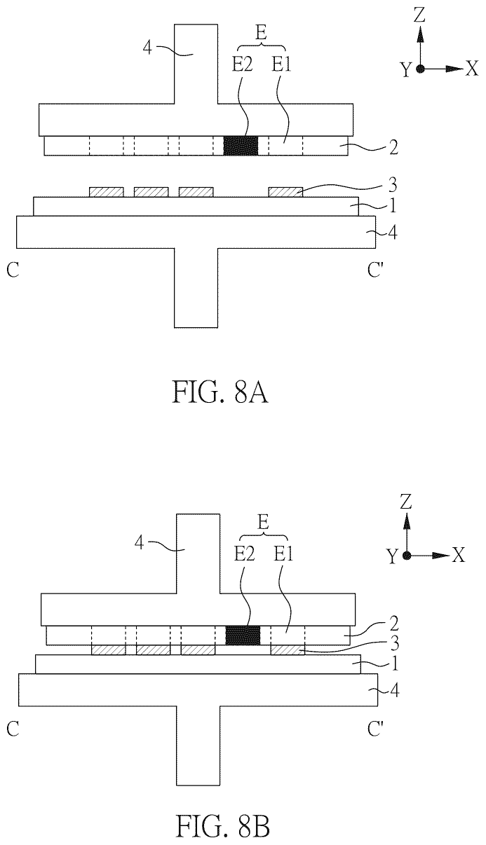

FIG. 7A is a top view of a carrier according to one embodiment of the present disclosure. FIG. 7B is a bottom view of a circuit substrate according to one embodiment of the present disclosure. FIG. 7C is a top view of a carrier and a circuit substrate after assembling according to one embodiment of the present disclosure. FIG. 8A and FIG. 8B are cross-sectional views showing a method for manufacturing an electronic device according to one embodiment of the present disclosure. FIG. 8A and FIG. 8B shows the cross-sectional views of the carrier and the circuit substrate of FIG. 7A to FIG. 7C along the line C-C′. In addition, the carrier and the circuit substrate shown in FIG. 7A to FIG. 7C are similar to those shown in FIG. 2A to FIG. 2C, and the manufacturing method shown in FIG. 8A and FIG. 8B is similar to that shown in FIG. 3A and FIG. 3B, except for the following differences.

In one embodiment of the present disclosure, the method for manufacturing an electronic device may comprise the following steps: providing a carrier 1 and a circuit substrate 2, wherein, as shown in FIG. 7A and FIG. 7B, the carrier portion CP of the carrier 1 may comprise a plurality of first marks M1, the circuit substrate 2 may comprise a plurality of second marks M2 and a plurality of electronic units E, the second marks M2 and the electronic units E are separated from each other in a top view direction Z of the carrier 1, and the electronic units E are detected and determined to be normal or defective. Herein, the defective electronic units E2 are represented by a black filling pattern in FIG. 7B. In one embodiment of the present disclosure, as shown in FIG. 7A, the carrier portions CP of the carrier 1 may further comprise a plurality of limiting portions 11 corresponding to the cover units 3. In one embodiment of the present disclosure, as shown in FIG. 7A and FIG. 7B, in the top view direction of the carrier 1 or the circuit substrate 2, the first marks M1 and the limiting portions 11 of the carrier 1 are not overlapped, and the second marks M2 and the electronic units E are not overlapped. Next, a plurality of cover units 3 are provided on the carrier 1. In one embodiment of the present disclosure, the cover units 3 may correspond to the normal electronic units E1, and the positions corresponding to the defective electronic units E2 may not be provided with the cover units 3 on the carrier 1. Thus, the waste of cover units 3 can be reduced and the effect of reducing manufacturing costs can be achieved.

Then, as shown in FIG. 8A, the circuit substrate 2 is disposed on the cover units 3, so that the first marks M1 of the carrier 1 and the second marks M2 of the circuit substrate 2 are overlapped in the top view direction Z of the carrier 1. In one embodiment of the present disclosure, as shown in FIG. 7A, the carrier 1 may not comprise the spacers SP and the fixing units CL shown in FIG. 2A. Thus, the carrier 1 and the circuit substrate 2 may be respectively temporarily fixed on the press machine 4 through electrostatic adsorption, hole extraction and grabbing, or other suitable methods, so that the first marks M1 of the carrier 1 and the second marks M2 of the circuit substrate 2 are overlapped in the top view direction Z of the carrier 1. Next, the circuit substrate 2 and the cover units 3 are vacuumed. More specifically, for example, the circuit substrate 2 and the carrier 1 provided with the cover units 3 may be placed in a reaction chamber (not shown in the figure) first, and then the reaction chamber is vacuumed; but the present disclosure is not limited thereto.

Then, as shown in FIG. 8B, the cover units 3 and the circuit substrate 2 are pressed so that the cover units 3 and the circuit substrate 2 are fixed to each other to form the structure shown in FIG. 7C. More specifically, the cover unit 3 and the circuit substrate 2 may be in contact through the movable press machine 4, followed by performing the step of pressing the cover units 3 and the circuit substrate 2. The cover units 3 and the circuit substrate 2 after pressing may be shown, for example, in FIG. 5B, and are not described again here.

In one embodiment of the present disclosure, as shown in FIG. 7A and FIG. 7B, when observing from the top view direction Z of the carrier 1 or the circuit substrate 2, the carrier portion CP of the carrier 1 and the circuit substrate 2 may respectively be rectangular; but the present disclosure is not limited thereto. Even not shown in the figure, in other embodiments of the present disclosure, in addition to the circular shapes shown in FIG. 2A to FIG. 2C and the rectangular shapes shown in FIG. 7A to FIG. 7C, the shapes of the carrier portion CP of the carrier 1 and the circuit substrate 2 may be designed according to the needs, and may be, for example, ellipse, prismatic or other suitable shapes.

In the present embodiment, except for the above differences, the materials and the detail features of the carrier 1, the cover unit 3 and the circuit substrate 2 may be as those described above, and are not described again here.

In the present disclosure, the waste of the cover units 3 can be reduced by not disposing the cover units 3 at the position corresponding to the defective electronic unit E2, thereby achieving the effect of reducing the manufacturing cost. Alternatively, in the present disclosure, the vacuum effect after the cover unit 3 and the circuit substrate 2 are assembled can be improved by disposing the spacers SP.

The above specific examples are to be construed as illustrative only and not in any way limiting of the remainder of the present disclosure.

Although the present disclosure has been explained in relation to its embodiment, it is to be understood that many other possible modifications and variations can be made without departing from the spirit and scope of the disclosure as hereinafter claimed.

1. A method for manufacturing an electronic device, comprising the following steps:
providing a carrier and a circuit substrate, wherein the carrier comprises a plurality of spacers, the circuit substrate comprises a plurality of electronic units, and the plurality of electronic units are detected and determined to be normal or defective;
providing a plurality of cover units on the carrier;
disposing the circuit substrate on the plurality of cover units so that the plurality of spacers support the circuit substrate, wherein there is a gap between the circuit substrate and the plurality of cover units, and the plurality of cover units correspond to the plurality of electronic units determined to be normal;
vacuuming the gap between the circuit substrate and the plurality of cover units;
moving the plurality of spacers to make the plurality of cover units and the circuit substrate contact each other; and
pressing the plurality of cover units and the circuit substrate to fix the plurality of cover units and the circuit substrate to each other.

2. The method of claim 1, wherein the carrier further comprises a plurality of fixing units, wherein the carrier and the circuit substrate are fixed by the plurality of fixing units before the step of vacuuming the gap, and fixing of the plurality of fixing units is released after the step of vacuuming the gap is started.

3. The method of claim 1, wherein the carrier further comprises a plurality of accommodation spaces respectively corresponding to the plurality of spacers, wherein a part of the plurality of spacers are moved to the plurality of accommodation spaces when moving the plurality of spacers.

4. The method of claim 1, wherein the carrier further comprises a plurality of limiting portions corresponding to the plurality of cover units.

5. The method of claim 4, wherein the plurality of limiting portions respectively have a depth ranging from 0.1 mm to 1 mm.

6. The method of claim 1, wherein the plurality of cover units respectively have a height ranging from 0.3 mm to 2 mm.

7. The method of claim 1, wherein the plurality of spacers respectively have a height ranging from 0.3 mm to 2 mm.

8. The method of claim 1, wherein the step of detecting the plurality of electronic units comprises checking appearances and electrical properties of the plurality of electronic units.

9. The method of claim 1, wherein the carrier comprises a carrier portion, the plurality of cover units are disposed on the carrier, and the carrier portion of the carrier and the circuit substrate are respectively rectangular.

10. The method of claim 1, wherein the carrier comprises a plurality of first marks and the circuit substrate comprises a plurality of second marks, wherein the method further comprise a step of: making the plurality of first marks of the carrier and the plurality of second marks of the circuit substrate overlap in a top view direction of the carrier before the step of pressing the plurality of cover units and the circuit substrate.

11. The method of claim 10, wherein the plurality of first marks and the plurality of spacers are not overlapped and the plurality of second marks and the plurality of electronic units are not overlapped in the top view direction of the carrier.

12. The method of claim 1, further comprising a step of: forming a first adhesive material on the plurality of electronic units and forming a second adhesive material on a substrate of the plurality of cover units before the step of providing the plurality of cover units on the carrier.

13. The method of claim 12, further comprising a step of: bonding the first adhesive material and the second adhesive material to form a third adhesive material after the step of pressing the plurality of cover units and the circuit substrate.

14. The method of claim 1, wherein the plurality of cover units are not disposed corresponding to the plurality of electronic units determined to be defective.

15. A method for manufacturing an electronic device, comprising the following steps:
providing a carrier and a circuit substrate, wherein the carrier comprises a plurality of first marks, the circuit substrate comprises a plurality of second marks and a plurality of electronic units, the plurality of second marks and the plurality of electronic units are separated from each other in a top view direction of the carrier, and the plurality of electronic units are detected and determined to be normal or defective;
providing a plurality of cover units on the carrier;
disposing the circuit substrate on the plurality of cover units so that the plurality of first marks of the carrier and the plurality of second marks of the circuit substrate are overlapped in the top view direction of the carrier, wherein the plurality of cover units correspond to the plurality of electronic units determined to be normal;
vacuuming the circuit substrate and the plurality of cover units; and
pressing the plurality of cover units and the circuit substrate to fix the plurality of cover units and the circuit substrate to each other.

16. The method of claim 15, wherein the carrier further comprises a plurality of limiting portions corresponding to the plurality of cover units.

17. The method of claim 16, wherein the plurality of first marks and the limiting portions are not overlapped and the plurality of second marks and the plurality of electronic units are not overlapped in the top view direction of the carrier.

18. The method of claim 15, wherein the plurality of cover units are not disposed corresponding to the plurality of electronic units determined to be defective.

19. The method of claim 15, wherein the step of detecting the plurality of electronic units comprises checking appearances and electrical properties of the plurality of electronic units.

20. The method of claim 15, wherein the carrier comprises a carrier portion, the plurality of cover units are disposed on the carrier, and the carrier portion of the carrier and the circuit substrate are respectively rectangular.
